(19) United States
(12) Patent Application Publication
(10) Pub. No.: US 2011/0174350 A1
(43) Pub. Date: Jul. 21, 2011

(54) THERMOELECTRIC GENERATOR

(76) Inventors: Alexander Gurevich, Petah Tikva (IL); Shimon Cohen, Tel Aviv (IL); Itzchak Heller, Ramat Gan (IL)

(21) Appl. No.: 12/689,253

(22) Filed: Jan. 19, 2010

(51) Int. Cl. H01L 35/30

(52) U.S. Cl. 136/205

(57) ABSTRACT

A thermoelectric generator including a plurality of thermoelectric elements placed on substrates, wherein a thermal conductivity of each substrate is defined as:

$${λ}_{S} \geq \frac{9 {λ}_{TE} {L}_{S}}{{L}_{TE}}$$

Where:
λ_{S}=thermal conductivity of each substrate,
λ_{TE}=thermal conductivity of each thermoelectric element,
L_{S}=thickness of each substrate,
L_{TE}=thickness of each thermoelectric element.

### FIELD OF THE INVENTION

The present invention relates generally to thermoelectric generators.

### BACKGROUND OF THE INVENTION

As is well known in the art, a thermoelectric generator generates electricity from a temperature difference between hot and cold parts. Many different heat sources have been used for supplying heat to the hot part of the thermoelectric generator, including solar radiation, industrial heat, car exhaust heat and many more.

Operation of the thermoelectric generator is based on the Seebeck effect which correlates the electrical field and the temperature gradient in the thermoelectric material. The voltage drop in the thermoelectric element (TE) is given by equation (1):

ΔV=αΔT (1)

Where:

ΔV=voltage drop,

α=Seebeck coefficient of the material,

ΔT=temperature difference.

If the TE is connected to an electrical load, the maximum value of the current (Iₘₐₓ) that passes is given by equation (2):

$${I}_{max} = \frac{αΔ T}{2 R} \qquad ( 2 )$$

Where:

R=the electrical resistance of the thermoelectric element and load.

The maximum electrical power (Qₘₐₓ) provided by the thermoelectric element is given by equation (3):

$${Q}_{max} = \frac{{α}^{2} Δ {T}^{2} S}{4 ρ L} \qquad ( 3 )$$

Where:

S=cross section area of thermoelectric element

L=thickness of thermoelectric element,

ρ=resistivity of thermoelectric material.

As seen from Eq. 3, the maximum output power is higher as the thermoelectric element gets thinner. Therefore, to provide higher output electrical power, the thick film thermoelectric elements should be kept thin, such as a thickness in the range of 0.01-1.0 mm However, in the prior art design of thermoelectric modules, the thermoelectric elements are connected directly to cold and hot base plates and the distance between the plates is close to the element thickness. This creates reverse heat conduction between the cold and the hot base plates and reduces the temperature difference between them, thereby reducing the performance and efficiency of the thermoelectric elements.

### SUMMARY OF THE INVENTION

The present invention seeks to provide an improved thermoelectric generator which overcomes the abovementioned problem of the prior art, as is described more in detail hereinbelow.

There is thus provided in accordance with an embodiment of the present invention, a thermoelectric generator including a plurality of thermoelectric elements placed on substrates, wherein a thermal conductivity of each substrate is defined as:

$${λ}_{S} \geq \frac{9 {λ}_{TE} {L}_{S}}{{L}_{TE}}$$

Where:

λ_{S}=thermal conductivity of each substrate,

λ_{TE}=thermal conductivity of each thermoelectric element,

L_{S}=thickness of each substrate,

L_{TE}=thickness of each thermoelectric element.

The thermoelectric elements may include thick film n-type and p-type thermoelectric elements, and may have a thickness of 0.01-1.0 mm The substrates may have a thickness of 1-20 mm

The thermoelectric generator may include a plurality of layers of the thermoelectric elements connected by electrically and thermally conductive elements.

In accordance with an embodiment of the present invention the layer adjacent the substrate receives only a portion of the total current passing through the thermoelectric elements.

In accordance with an embodiment of the present invention the layers have different thicknesses.

In accordance with an embodiment of the present invention the substrate includes heat transfer fins.

In accordance with an embodiment of the present invention the thermoelectric elements and the substrates are mounted on an electrically conductive folded base.

In accordance with an embodiment of the present invention the thermoelectric elements are mounted on a porous or perforated substrate.

In accordance with an embodiment of the present invention a phase change material (PCM) is disposed on one side of the thermoelectric elements.

### BRIEF DESCRIPTION OF THE DRAWINGS

The present invention will be understood and appreciated more fully from the following detailed description taken in conjunction with the drawings in which:

FIG. 1 is a simplified illustration of a thermoelectric element mounted on a substrate, in accordance with an embodiment of the present invention;

FIGS. 2 and 3 are simplified illustrations of layers of thermoelectric elements mounted on substrates, in accordance with two embodiments of the present invention;

FIGS. 4A and 4B are simplified side and top view illustrations, respectively, of a thermoelectric element mounted on a substrate with heat transfer fins, in accordance with an embodiment of the present invention;

FIGS. 5 and 6 are simplified illustrations of thermoelectric elements and substrates mounted on an electrically conductive folded base, in accordance with embodiments of the present invention;

FIG. 7 is a simplified illustration of a thermoelectric element mounted on a porous or perforated substrate, in accordance with embodiments of the present invention; and

FIGS. 8A and 8B are simplified illustrations of a thermoelectric generator panel, constructed and operative in accordance with an embodiment of the present invention.

### DETAILED DESCRIPTION OF EMBODIMENTS

As mentioned in the background, in the prior art, the thermoelectric elements are connected directly to cold and hot base plates and the distance between the plates is close to the element thickness. This creates reverse heat conduction between the cold and the hot base plates and reduces the temperature difference between them, thereby reducing the performance and efficiency of the thermoelectric elements.

The thermal loss (Qₗₒₛ) due to reverse heat conduction between the cold and the hot base plates is given by equation (4):

$${Q}_{los} = \frac{{λ}_{ins} S Δ T}{L} \qquad ( 4 )$$

Where:

λᵢₙₛ=thermal conductivity of insulating material

S=cross section area of thermoelectric element

ΔT=temperature difference

L=thickness of thermoelectric element

As seen from Eq. 4, the heat loss increases with reduced element thickness.

Reference is now made to FIG. 1. In accordance with an embodiment of the present invention, in order to reduce the thermal losses, a thin thermoelectric element 10 (whose thickness is typically, although not necessarily, in the range of 0.01-1.0 mm) is placed on a thick substrate 12, whose thickness is in the range of 10-100 times that of the TE element (typically, although not necessarily, in the range of 1-20 mm)

However, this alone does not solve the problem, because the temperature drop through substrate 12 increases with increased thickness of the substrate. The increased temperature drop through substrate 12 reduces the temperature drop on TE element 10, and this significantly reduces the output power, because according to Equation 3 above, the output power is a function of ΔT².

In accordance with an embodiment of the present invention, to reduce the temperature drop on substrate 12, the material of the substrate 12 is selected to have a high thermal conductivity λ_{S} meeting the following condition:

$${λ}_{S} \geq \frac{9 {λ}_{TE} {L}_{S}}{{L}_{TE}} \qquad ( 5 )$$

Where:

λ_{S}=thermal conductivity of substrate material,

λ_{TE}=thermal conductivity of thermoelectric material

L_{S}=thickness of the substrate,

L_{TE}=thickness of thermoelectric element.

Suitable materials for meeting this criterion include, but are not limited to, silver, silver alloys, copper, copper alloys, gold and gold alloys. When the thermoelectric generator element 10 is connected to a load, electrical current passes through the TE element 10 and a cooling effect occurs at the contact between TE element 10 and substrate 12. The cooling power Q_{c} is calculated from the following equation:

$${Q}_{c} = α {IT}_{H} - 0.5 {I}^{2} {R}_{TE} + \frac{{λ}_{TE} S Δ T}{{L}_{TE}} \qquad ( 6 )$$

Where:

T_{H}=temperature of the hot junction,

S=cross-sectional area of TE element

This presents another problem: The cooling power reduces the effective heating power incoming to the hot junction, thereby lowering the hot junction temperature, which results in the total ΔT being reduced.

From Equation 6, the cooling power increases with increasing current. In accordance with an embodiment of the present invention, this problem is solved by reducing the current passing through the hot junction, that is, at the TE element that actually contacts the substrate, thereby improving the total power output. One way of achieving this is shown in FIG. 2. The current is distributed between a plurality of layers (e.g., 2-4 layers) of thermoelectric material and the last layer which is connected to the hot junction receives only a portion of the total current passing through the load (e.g., 25-50% of the total current). Conductive elements 15 bridge between adjacent stacks of TE elements 10.

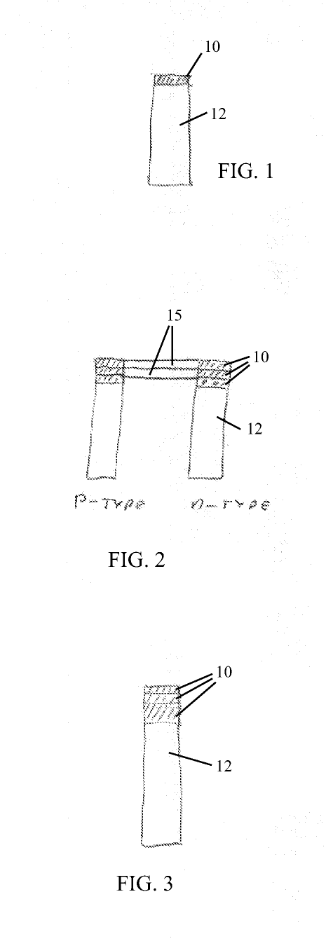

Another way of achieving this is shown in FIG. 3. In this embodiment, current passing through the last layer (closest to substrate 12) is reduced by choosing layers of thermoelectric material with different thicknesses, wherein the last layer has the lowest thickness so that the current passing through the hot junction is minimal.

As previously mentioned, the output electrical power of the thermoelectric generator increases significantly with increasing temperature difference on the TE element. Improvements on the hot junction have been described above.

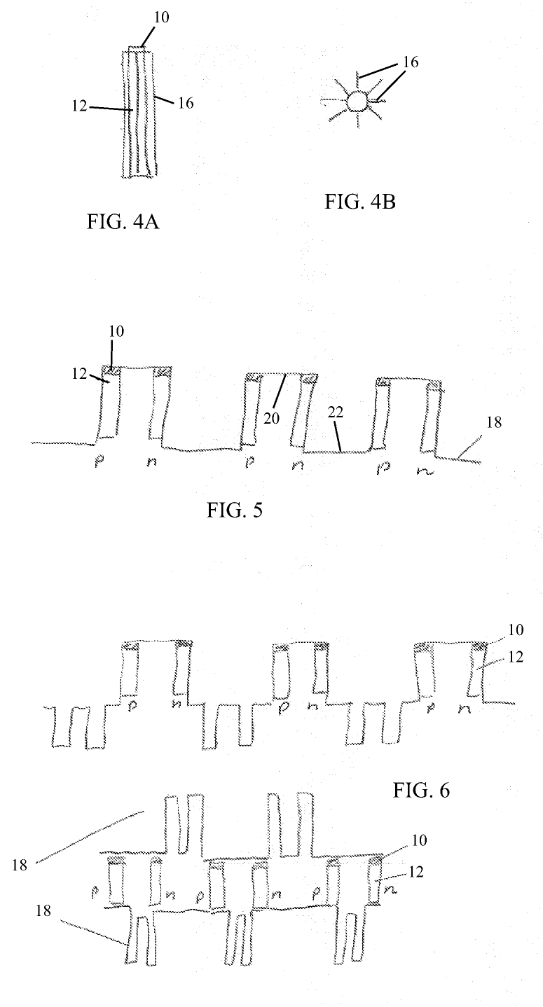

Another way to improve ΔT is to reduce the temperature on the cold junction. In accordance with an embodiment of the present invention, this is achieved by reducing the temperature of the substrate, such as by convective heat transfer, as shown in FIGS. 4A-4B. The substrate 12 has a large heat exchange surface area, such as being made from an extrusion with radial heat transfer fins 16.

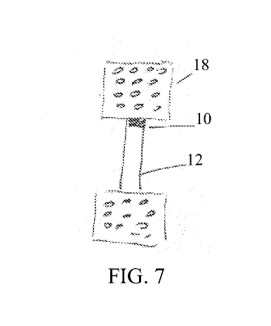

Reference is now made to FIG. 5. In this embodiment, an electrically conductive folded base 18 (e.g., strip or plate) is provided and the thermoelectric elements 10 and substrates 12 are attached to upper folds 20 of the folded base 18. Alternatively, they could be attached to bottom folds 22 of base 18. The thermoelectric elements 10 are connected electrically in series such that all conductors pass alternatively between n-type and p-type elements. This arrangement lends itself easily for further connection to heat exchange elements. For example, the folded base 18 can serve as cooling fins for forced or natural convection, as an integral part of a thermoelectric elements assembly. The fins can be made on one side (cold or hot) as shown in FIG. 5, or on both sides of the TE elements as shown in FIG. 6. In order to provide more efficient heat exchange from the fins, the folded base 18 can be made from a porous or perforated material, as shown in FIG. 7. An advantage of the structures of FIGS. 5-7 is direct contact between TE element 10 and the cooling fins of the base 18. This feature reduces the contact thermal resistance, and as a result increases the ΔT on TE element 10.

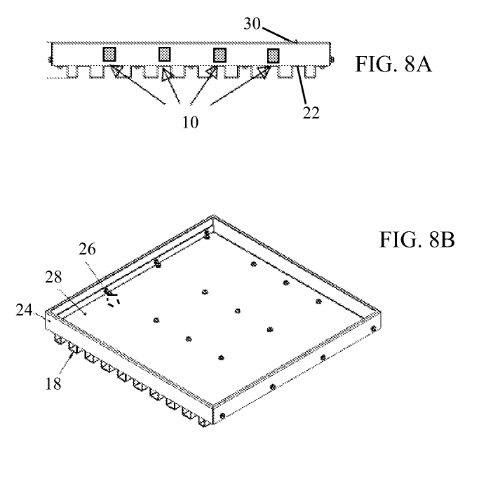

Reference is now made to FIGS. 8A and 8B, which illustrate a thermoelectric generator panel, constructed and operative in accordance with an embodiment of the present invention. Thermoelectric elements 10 are mounted on bottom folds 22 of base 18 mounted in a frame 24, and a selective coating or photovoltaic cells 26 (or other solar energy modules) are mounted on the other side of base 18. The frame 24 is covered with glass plates 28 or other suitable plates.

To prolong operation of the thermoelectric generator panel in conditions when heat input is non-existent (for example, at night time for solar generator), a phase change material (PCM) 30 is disposed on the cold/hot side of TE elements. Optionally porous fins can be filled by the PCM. In this case, the PCM has direct contact with the fins with minimal contact thermal resistance between the TE element and the PCM.

It will be appreciated by persons skilled in the art that the present invention is not limited by what has been particularly shown and described hereinabove. Rather the scope of the present invention includes both combinations and subcombinations of the features described hereinabove as well as modifications and variations thereof which would occur to a person of skill in the art upon reading the foregoing description and which are not in the prior art.

What is claimed is:

1. A thermoelectric generator comprising:
a plurality of thermoelectric elements placed on substrates, wherein a thermal conductivity of each substrate is defined as:
$${λ}_{S} \geq \frac{9 {λ}_{TE} {L}_{S}}{{L}_{TE}}$$
Where:
λ_{S}=thermal conductivity of each substrate,
λ_{TE}=thermal conductivity of each thermoelectric element,
L_{S}=thickness of each substrate,
L_{TE}=thickness of each thermoelectric element.

2. The thermoelectric generator according to claim 1, wherein said thermoelectric elements comprise thick film n-type and p-type thermoelectric elements.

3. The thermoelectric generator according to claim 1, wherein said thermoelectric elements each have a thickness of 0.01-1.0 mm

4. The thermoelectric generator according to claim 1, wherein said substrates each have a thickness of 1-20 mm

5. The thermoelectric generator according to claim 1, comprising a plurality of layers of said thermoelectric elements connected by electrically and thermally conductive elements.

6. The thermoelectric generator according to claim 5, wherein the layer adjacent the substrate receives only a portion of the total current passing through said thermoelectric elements.

7. The thermoelectric generator according to claim 5, wherein the layers have different thicknesses.

8. The thermoelectric generator according to claim 1, wherein said substrate comprises heat transfer fins.

9. The thermoelectric generator according to claim 1, wherein said thermoelectric elements and said substrates are mounted on an electrically conductive folded base.

10. The thermoelectric generator according to claim 1, wherein said thermoelectric elements are mounted on a porous or perforated substrate.

11. The thermoelectric generator according to claim 1, wherein a phase change material (PCM) is disposed on one side of said thermoelectric elements.
